(19) United States
(12) Patent Application Publication
(10) Pub. No.: US 2026/0247990 A1
(43) Pub. Date: Aug. 20, 2026

(54) METHOD FOR PRODUCING WIRING STRUCTURE

(71) Applicant: Resonac Corporation, Minato-ku, Tokyo (JP)

(72) Inventors: Masaya TOBA, Minato-ku, Tokyo (JP); Kazuyuki MITSUKURA, Minato-ku, Tokyo (JP)

(21) Appl. No.: 18/859,558

(22) PCT Filed: Oct. 24, 2022
(86) PCT No.: PCT/JP2022/039544

§ 371 Date: Oct. 24, 2024

(51) Int. Cl. H10W 70/06; H10W 70/695

(52) U.S. Cl. CPC H10W 70/06; H10W 70/695

(57) ABSTRACT

A method for producing a wiring structure is disclosed. The method for producing a wiring structure includes forming, in a support substrate, a modification region that is along a main surface of the support substrate and that is exposed on the main surface; forming a conductor layer on the main surface so as to adhere with the modification region; forming a wiring on the conductor layer; forming an insulating layer on the conductor layer to cover the wiring; separating the support substrate from the conductor layer; and removing the conductor layer.

### TECHNICAL FIELD

The present disclosure relates to a method for producing a wiring structure.

### BACKGROUND ART

In a wiring structure used for a semiconductor device, an embedded trace substrate (ETS) method is known as a method capable of forming wirings at high density (see Patent Literatures 1 and 2). In the ETS method, for example, a conductor layer to be a seed layer is formed on a support substrate, and wiring is formed on the conductor layer by electroplating or the like. Thereafter, an insulating layer is formed so as to cover the wiring, and the support substrate and the conductor layer are removed.

### CITATION LIST

### Patent Literature

Patent Literature 1: U.S. Pat. No. 10,622,292

Patent Literature 2: U.S. Pat. No. 10,483,196

### SUMMARY OF INVENTION

### Technical Problem

The conductor layer functioning as the seed layer is removed by being dissolved using, for example, an etching solution. When the conductor layer is removed, unevenness may occur in the degree of dissolution. In this case, for example, dissolution with respect to a part of the conductor layer excessively proceeds, and the wiring formed on the conductor layer may be removed. As a result, the yield decreases in the production of the wiring structure.

An object of the present disclosure is to provide a method for producing a semiconductor device capable of improving a yield in producing a wiring structure.

### Solution to Problem

As one aspect, the present disclosure relates to a method for producing a wiring structure. The method for producing a wiring structure includes forming, in a support substrate, a modification region that is along a main surface of the support substrate and that is exposed on the main surface; forming a conductor layer on the main surface so as to adhere with the modification region; forming a wiring on the conductor layer; forming an insulating layer on the conductor layer to cover the wiring; separating the support substrate from the conductor layer; and removing the conductor layer.

In this production method, the modification region exposed to the main surface is formed in the support substrate, and the conductor layer is formed on the main surface of the support substrate so as to adhere with the modification region. In this case, the adhesion of the conductor layer with respect to the support substrate is improved by the modification region. As a result, the conductor layer can be stably formed on the support substrate, and for example, the conductor layer can be formed thin. As the conductor layer becomes thinner, the time required for removing the conductor layer can be shortened, so that unevenness hardly occurs in the degree of dissolution of the conductor layer. Therefore, when the conductor layer is removed, it is possible to suppress removal of even the wiring formed on the conductor layer. Therefore, according to this production method, the yield in producing the wiring structure can be improved.

In the above-described method for producing the wiring structure, the modification region may include a hole communicating from the main surface. In this case, a part of the conductor layer enters the hole of the modification region, and the adhesion between the support substrate and the conductor layer is improved by the anchor effect.

In the above-described method for producing the wiring structure, the forming the modification region may include forming the modification region by performing plasma treatment on the support substrate. In this case, the modification region can be more reliably formed in the support substrate.

In the above-described method for producing the wiring structure, the adhesion strength between the conductor layer and the modification region may be 0.1 to 1.0 N/mm. When the adhesion strength between the conductor layer and the modification region is greater than or equal to 0.1 N/mm, the conductor layer can be more stably formed on the support substrate. Since the adhesion strength between the conductor layer and the modification region is less than or equal to 1.0 N/mm, the support substrate can be easily separated in separating the support substrate from the conductor layer.

In the above-described method for producing the wiring structure, the thickness of the modification region may be 50 nm to 500 nm. When the thickness of the modification region is greater than or equal to 50 nm, adhesion with the conductor layer can be sufficiently secured. When the thickness of the modification region is less than or equal to 500 nm, brittleness of the modification region can be suppressed.

In the above-described method for producing the wiring structure, the thickness of the conductor layer may be 50 nm to 1 μm. When the thickness of the conductor layer is greater than or equal to 50 nm, resistance at the time of power supply can be reduced when forming the conductor layer by electroplating, so that electroplating can be easily performed. When the thickness of the conductor layer is less than or equal to 1 μm, the time required for removing the conductor layer can be further shortened.

In the above-described method for producing the wiring structure, the forming the wiring includes forming a resist on the conductor layer, forming an opening pattern in which the conductor layer is exposed in the resist, filling the opening pattern with a conductive material by electroplating to form the wiring, and removing the resist. In this case, the fine wiring can be easily formed.

In the above-described method for producing the wiring structure, the resist may be formed of a photosensitive material. In this case, a fine pattern can be formed through exposure and development steps.

In the above-described method for producing the wiring structure, the insulating layer may be formed of a thermosetting resin. In this case, the adhesiveness of the insulating layer with respect to the wiring can be improved.

The above-described method for producing a wiring structure further including forming a plurality of multilayered wiring layers by performing a series of steps including, after forming the insulating layer, forming another conductor layer on the insulating layer, forming another wiring on the another conductor layer, and forming another insulating layer to cover the another wiring one or more times. In this case, a wiring structure including a multilayered wiring layer can be produced.

### Advantageous Effects of Invention

According to one aspect of the present disclosure, it is possible to improve a yield in production of a semiconductor device.

### BRIEF DESCRIPTION OF DRAWINGS

FIGS. 1A and 1B are cross-sectional views illustrating a method for producing a wiring structure according to an embodiment.

FIGS. 2A and 2B are cross-sectional views illustrating the method for producing the wiring structure according to an embodiment.

FIGS. 3A and 3B are cross-sectional views illustrating the method for producing the wiring structure according to an embodiment.

FIGS. 4A and 4B are cross-sectional views illustrating the method for producing the wiring structure according to an embodiment.

FIG. 5 is a cross-sectional view illustrating the method for producing the wiring structure according to an embodiment.

FIGS. 6A and 6B are cross-sectional views illustrating a method for producing a wiring structure according to a modified example.

FIG. 7 is a cross-sectional view illustrating the method for producing the wiring structure according to the modified example.

### DESCRIPTION OF EMBODIMENTS

Hereinafter, some embodiments of the present disclosure will be described in detail with reference to the drawings as necessary. In the following description, the same or corresponding portions are denoted by the same reference numerals, and redundant description will be omitted. Furthermore, unless otherwise specified, the positional relationship such as up, down, left, and right is based on the positional relationship illustrated in the drawings. Furthermore, the dimensional ratios in the drawings are not limited to the illustrated ratios.

In the present specification, the numerical range indicated using “to” includes the numerical values described before and after “to” as the minimum value and the maximum value, respectively. In the numerical ranges described in stages in the present specification, the upper limit value or the lower limit value described in one numerical range may be replaced with the upper limit value or the lower limit value of the numerical range described in other stages. In addition, in the numerical range described in the present specification, the upper limit value or the lower limit value of the numerical range may be replaced with a value shown in the Examples.

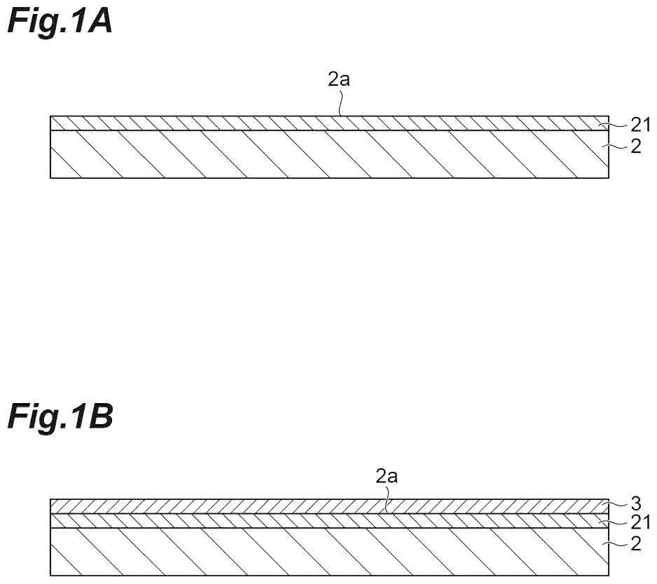

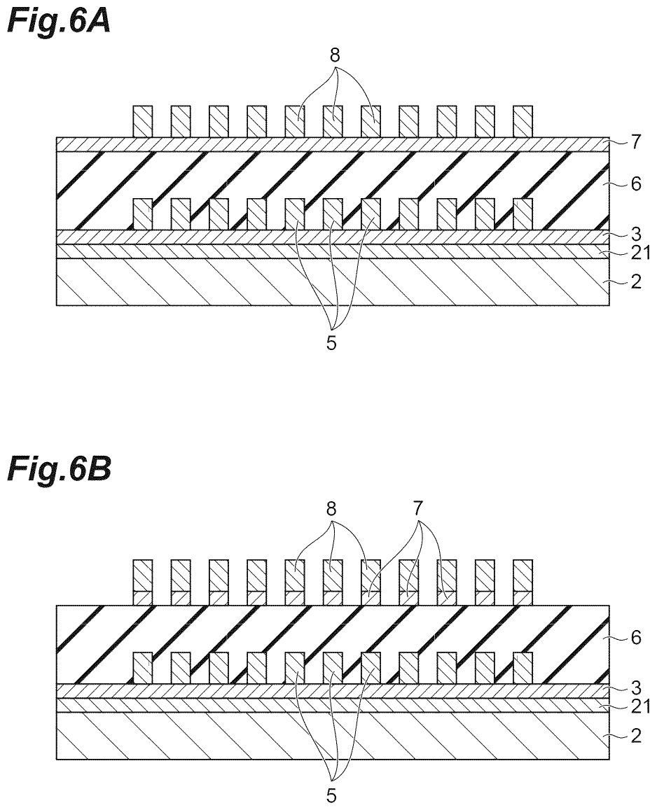

A method for producing a wiring structure 1 (see FIG. 6) according to an embodiment will be described with reference to FIGS. 1 to 5. FIGS. 1 to 5 are cross-sectional views illustrating a method for producing the wiring structure 1. The wiring structure 1 can be applied to a semiconductor device. For example, the wiring structure 1 may be used to connect semiconductor chips in a semiconductor device. The wiring structure 1 is produced by using, for example, an embedded trace substrate (ETS) method.

The wiring structure 1 is produced through, for example, the following steps (a) to (f).
(a) step of forming, in a support substrate 2, a modification region 21 that is along a main surface 2a of the support substrate 2 and that is exposed on the main surface 2a.
(b) step of forming a conductor layer 3 on the main surface 2a so as to adhere with the modification region 21.
(c) step of forming a wiring 5 on the conductor layer 3.
(d) step of forming an insulating layer 6 on the conductor layer 3 so as to cover the wiring 5.
(e) step of separating the support substrate 2 from the conductor layer 3.

(f) step of removing the conductor layer 3.

### Step (a)

Step (a) will be described with reference to FIG. 1A. Step (a) is a step of forming the modification region 21 in the support substrate 2. In step (a), first, the support substrate 2 is prepared. The support substrate 2 may be, for example, a silicon plate, a glass plate, a stainless steel (SUS) plate, or a substrate containing glass cloth. The support substrate 2 is preferably a substrate having high rigidity.

The thickness of the support substrate 2 may be, for example, 0.2 mm to 2.0 mm. When the thickness of the support substrate 2 is greater than or equal to 0.2 mm, handling is facilitated. On the other hand, when the thickness of the support substrate 2 is less than or equal to 2.0 mm, the material cost of the wiring structure 1 can be suppressed. The support substrate 2 may have a wafer shape or a panel shape. The size of the support substrate 2 is not limited. The support substrate 2 may be a wafer-like substrate having a diameter of 200 mm, 300 mm, or 450 mm, or a rectangular panel-like substrate having one side of 300 mm to 700 mm.

Next, the modification region 21 is formed in the support substrate 2. The modification region 21 is formed along the main surface 2a of the support substrate 2 and so as to be exposed on the main surface 2a. The modification region 21 is formed in layers in the support substrate 2. The thickness of the modification region 21 may be, for example, 50 nm to 500 nm. The modification region 21 may be formed over the entire main surface 2a or may be formed on a part of the main surface 2a. The modification region 21 has holes communicating from the main surface 2a. The size of the holes measured by the transmission electron microscope or the scanning electron microscope may be, for example, 50 to 500 nm. The size of the holes is not limited. A part of the conductor layer 3 described later enters the holes of the modification region 21. When the conductor layer 3 enters the holes of the modification region 21, adhesion between the support substrate 2 and the conductor layer 3 is improved by the anchor effect. That is, the modification region 21 functions as an adhesion layer that adheres to the conductor layer 3.

The modification region 21 may be formed, for example, by performing plasma treatment on the support substrate 2. The plasma used for the plasma treatment may be, for example, oxygen plasma, argon plasma, nitrogen plasma, helium plasma, or fluorine-containing plasma. As an example, when the support substrate 2 is a silicon plate, a glass plate, or a SUS plate, the modification region 21 can be suitably formed by using fluorine-containing plasma. A method for forming the modification region 21 is not limited. The modification region 21 may be formed using, for example, ozone water modification, ultraviolet-ozone modification, or the like.

### Step (b)

Step (b) will be described with reference to FIG. 1B. Step (b) is a step of forming the conductor layer 3 on the main surface 2a so as to adhere with the modification region 21. The conductor layer 3 includes one layer or a plurality of multilayered layers. The conductor layer 3 may be formed of, for example, Ti, Ni, NiP, NiB, Co, TaW, or CoNiP. The method for forming the conductor layer 3 may be, for example, electroless plating, sputtering, coating, or the like. The thickness of the conductor layer 3 may be 50 nm to 1 um or 50 nm to 500 nm.

The conductor layer 3 is formed directly on the main surface 2a (modification region 21) of the support substrate 2. The conductor layer 3 formed on the support substrate 2 is adhered with the modification region 21 as described above. The adhesion strength between the conductor layer 3 and the modification region 21 may be, for example, 0.1 to 1.0 N/mm or 0.5 to 1.0 N/mm. Adhesion strength is measured by 90°peel test by autograph. The peel test conditions are not particularly limited, but for example, the peel test piece width is 10 mm, and the peel speed is 10 mm/min.

### Step (c)

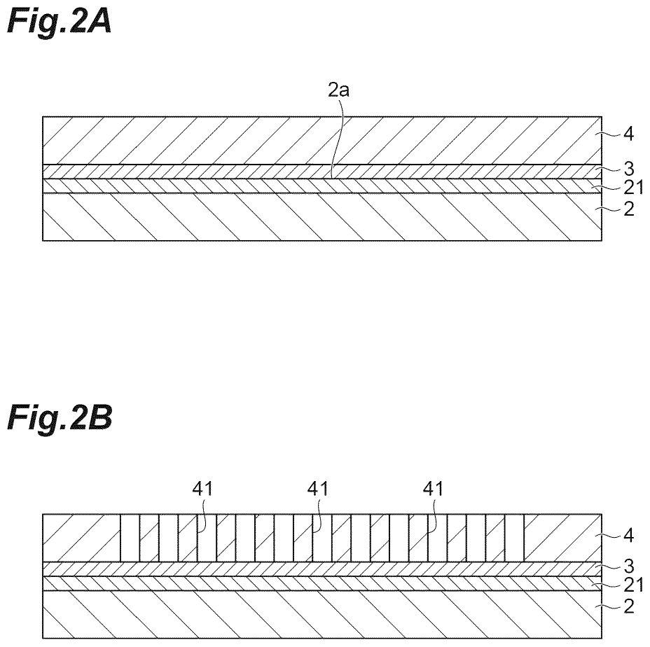

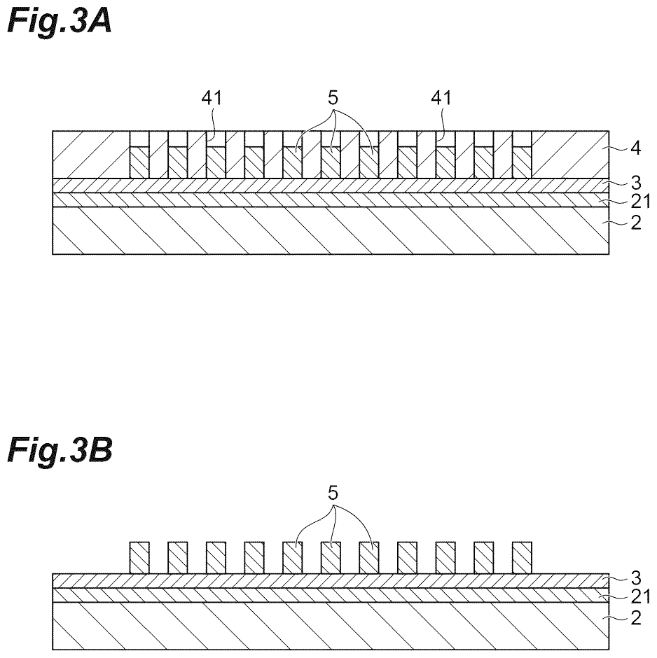

Step (c) will be described with reference to FIGS. 2 and 3. Step (c) is a step of forming a wiring 5 on the conductor layer 3. In step (c), first, as illustrated in FIG. 2A, a resist 4 is formed on the conductor layer 3. The resist 4 is a resist for forming a wiring (circuit). The resist 4 may be formed of, for example, a photosensitive material. The photosensitive material may have an insulating property. The resist 4 may be a commercially available resist. Examples of the commercially available resist include a negative film-shaped photosensitive resist (produced by Showa Denko Materials Co., Ltd., Photec RY-5107UT).

Next, as illustrated in FIG. 2B, an opening pattern 41 (resist pattern) is formed in the resist 4. The opening pattern 41 penetrates the resist 4 in the thickness direction of the resist 4. The conductor layer 3 is exposed in the opening pattern 41. When the resist 4 is formed of a photosensitive material, the opening pattern 41 may be formed by exposing and developing the resist 4. As an example, first, the resist 4 is formed (film formed) using a roll laminator. Subsequently, the photo tool on which the pattern is formed is brought into close contact with the resist 4, and exposure is performed using an exposure machine. Thereafter, for example, spray development is performed with an aqueous sodium carbonate solution to form the opening pattern 41. A positive photosensitive resist may be used instead of the negative resist. The width of the opening pattern 41 may be, for example, 1 μm to 30 μm, 3 μm to 30 μm, or 5 μm to 30 μm.

Next, as illustrated in FIG. 3A, the opening pattern 41 is filled with a conductive material to form the wiring 5. The wiring 5 may be formed by, for example, supplying power to the conductor layer 3 and performing electroplating. The electroplating may be, for example, copper electroplating. The thickness of the wiring 5 may be, for example, 1 μm to 10 μm, 3 μm to 15 μm, or 5 μm to 20 μm. Next, as illustrated in FIG. 3B, the resist 4 is separated and removed. The resist 4 may be separated using a commercially available separating solution.

### Step (d)

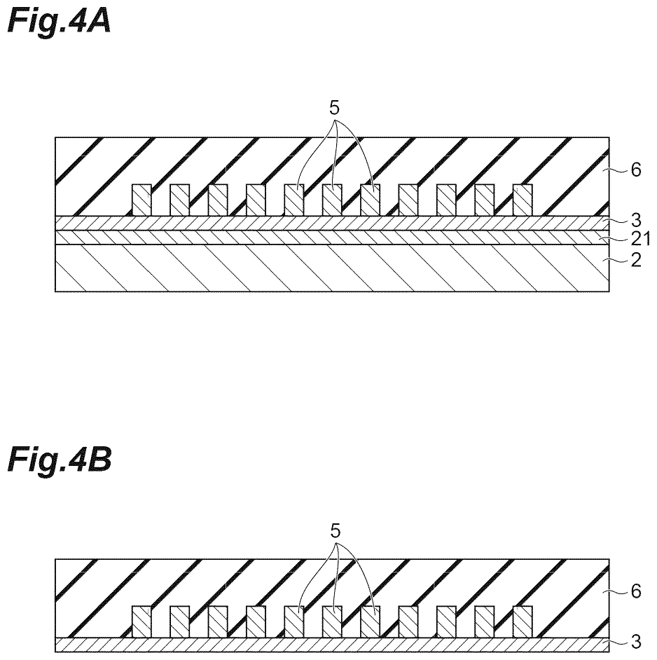

Step (d) will be described with reference to FIG. 4A. Step (d) is a step of forming the insulating layer 6 on the conductor layer 3 so as to cover the wiring 5. The wiring 5 is embedded in the insulating layer 6. The insulating layer 6 may be formed of, for example, a thermosetting resin. The insulating layer 6 may be, for example, a build-up material, glass cloth, or an insulating material containing an inorganic filler.

The material of the insulating layer 6 may be a liquid or film-shaped material. From the viewpoint of improving the embeddability of the wiring 5, the material of the insulating layer 6 is preferably in a film shape. When a film-shaped insulating material is used, the step of laminating the insulating material is preferably a low-temperature step, and the insulating material is preferably a photosensitive insulating film or a thermosetting insulating film that can be laminated at 40° C. to 120° C. An insulating film that can be laminated at a temperature of higher than or equal to 40° C. tends to have good handleability without excessively strong tackiness at room temperature. On the other hand, an insulating film that can be laminated at a temperature of lower than or equal to 120° C. tends to have small warpage after lamination.

The coefficient of thermal expansion of the insulating layer 6 after curing is preferably less than or equal to 80 ppm/° C. from the viewpoint of suppressing warpage, and more preferably less than or equal to 70 ppm/°° C. from the viewpoint of obtaining high reliability. The coefficient of thermal expansion of the insulating layer 6 after curing is preferably greater than or equal to 20 ppm/° C. from the viewpoint of stress relaxation of the insulating material and obtaining a high-definition pattern. The thickness of the insulating layer 6 may be 5 μm to 50 μm or 10 μm to 30 μm.

### Step (e)

Step (e) will be described with reference to FIG. 4B. Step (e) is a step of separating the support substrate 2 from the conductor layer 3. The support substrate 2 may be separated manually or by using a dedicated separating device. By the separating of the support substrate 2, the surface of the conductor layer 3 opposite to the insulating layer 6 is exposed.

### Step (f)

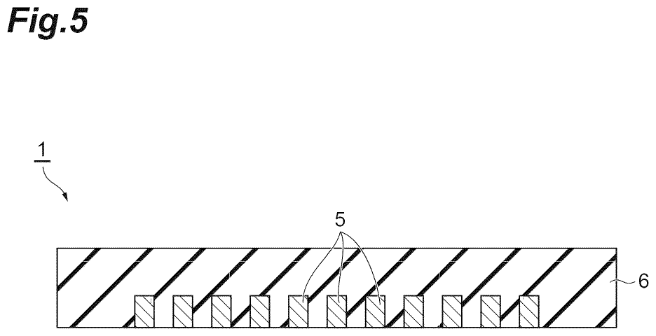

Step (f) will be described with reference to FIG. 5. Step (f) is a step of removing the conductor layer 3. The conductor layer 3 is removed by, for example, etching. Etching for removing the conductor layer 3 may be performed using a commercially available etching solution. For example, when the conductor layer 3 is formed of Ti, a Ti etching solution (produced by Mitsubishi Gas Chemical Co., Inc., WLC-T) may be used. When the conductor layer 3 is formed of Ni, a Ni etching solution (produced by JCU Corporation, EVATOR STRIP) may be used. The etching solution may be applied to a surface of the conductor layer 3 opposite to the insulating layer 6. Through the above steps, as illustrated in FIG. 5, the wiring structure 1 including the wiring 5 and the insulating layer 6 is produced.

As described above, in the method for producing the wiring structure 1 according to the present embodiment, the modification region 21 exposed to the main surface 2a is formed in the support substrate 2, and the conductor layer 3 is formed on the main surface 2a of the support substrate 2 so as to adhere with the modification region 21. In this case, the adhesion of the conductor layer 3 with respect to the support substrate 2 is improved by the modification region 21. As a result, the conductor layer 3 can be stably formed on the support substrate 2, and for example, the conductor layer 3 can be formed thin. As the conductor layer 3 becomes thinner, the time required for removing the conductor layer 3 can be shortened, so that unevenness hardly occurs in the degree of dissolution of the conductor layer 3. Therefore, when the conductor layer 3 is removed, it is possible to suppress removal of even the wiring 5 formed on the conductor layer 3. Therefore, according to this production method, the yield in producing the wiring structure 1 can be improved.

In the method for producing the wiring structure 1 of the present embodiment, the modification region 21 has holes communicating from the main surface 2a. In this case, a part of the conductor layer 3 enters the holes of the modification region 21, and the adhesion between the support substrate 2 and the conductor layer 3 is improved by the anchor effect.

In the method for producing the wiring structure 1 of the present embodiment, in step (a) of forming the modification region 21, the modification region 21 may be formed by performing plasma treatment on the support substrate 2. In this case, the modification region 21 can be more reliably formed in the support substrate 2.

In the method for producing the wiring structure 1 of the present embodiment, the adhesion strength between the conductor layer 3 and the modification region 21 may be 0.1 to 1.0 N/mm. When the adhesion strength between the conductor layer 3 and the modification region 21 is greater than or equal to 0.1 N/mm, the conductor layer 3 can be more stably formed on the support substrate 2. Since the adhesion strength between the conductor layer 3 and the modification region 21 is less than or equal to 1.0 N/mm, the support substrate 2 can be easily separated in step (e) of separating the support substrate 2 from the conductor layer 3.

In the method for producing the wiring structure 1 of the present embodiment, the thickness of the modification region 21 may be 50 nm to 500 nm. When the thickness of the modification region 21 is greater than or equal to 50 nm, adhesion with the conductor layer 3 can be sufficiently secured. When the thickness of the modification region 21 is less than or equal to 500 nm, brittleness of the modification region 21 can be suppressed.

In the method for producing the wiring structure 1 of the present embodiment, the thickness of the conductor layer 3 may be 50 nm to 1 um. When the thickness of the conductor layer 3 is greater than or equal to 50 nm, resistance at the time of power supply can be reduced when forming the conductor layer 3 by electroplating, so that electroplating can be easily performed. When the thickness of the conductor layer 3 is less than or equal to 1 μm, the time required for removing the conductor layer 3 can be further shortened.

In the method for producing the wiring structure 1 of the present embodiment, step (c) of forming the wiring 5 includes a step of forming a resist 4 on the conductor layer 3, a step of forming an opening pattern 41 in which the conductor layer 3 is exposed in the resist 4, a step of filling the opening pattern 41 with a conductive material by electroplating to form the wiring 5, and a step of removing the resist 4. In this case, the fine wiring 5 can be easily formed.

In the method for producing the wiring structure 1 of the present embodiment, the resist 4 may be formed of a photosensitive material. In this case, a fine pattern can be formed through exposure and development steps.

In the method for producing the wiring structure 1 of the present embodiment, the insulating layer 6 may be formed of a thermosetting resin. In this case, the adhesiveness of the insulating layer 6 with respect to the wiring 5 can be improved.

Although the embodiments of the present disclosure have been described in detail above, the present disclosure is not limited to the above embodiments.

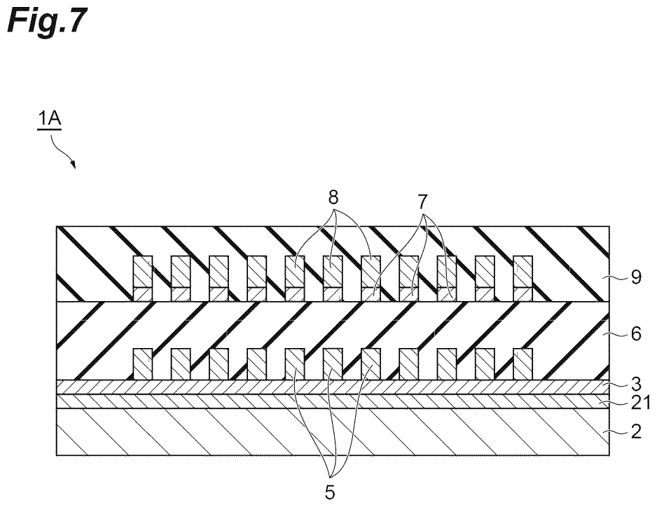

A method for producing a wiring structure 1A (see FIG. 7) according to a modified example will be described with reference to FIGS. 6 and 7. FIGS. 6 and 7 are cross-sectional views illustrating a method for producing the wiring structure 1A. In the production method according to the modified example, after step (d) of forming the insulating layer 6, a step of multilayering another wiring layer on the insulating layer 6 is performed one or more times to form a plurality of multilayered wiring layers. Specifically, first, as illustrated in FIG. 6A, after step (d) of forming the insulating layer 6, a conductor layer 7 (seed layer) is formed on the insulating layer 6. The method for forming the conductor layer 7 may be similar to the method for forming the conductor layer 3. Next, a wiring 8 is formed on the conductor layer 7. The method for forming the wiring 8 may be similar to the method for forming the wiring 5.

Next, as illustrated in FIG. 6B, a portion of the conductor layer 7 exposed from the wiring 8 (a portion not overlapping the wiring 8) is removed. As a result, the conductor layer 7 remaining on the insulating layer 6 functions as wiring together with the wiring 5. When the conductor layer 7 is removed by etching, a commercially available etching solution may be used. For example, when the conductor layer 7 is formed of Ti, a Ti etching solution (produced by Mitsubishi Gas Chemical Co., Inc., WLC-T) may be used. When the conductor layer 7 is formed of Ni, a Ni etching solution (produced by JCU Corporation, EVATOR STRIP) may be used.

Next, as illustrated in FIG. 7, an insulating layer 9 is formed on the insulating layer 6 so as to cover the wiring 8 and the conductor layer 7. The wiring 8 and the conductor layer 7 are embedded in the insulating layer 9. The method for forming the insulating layer 9 may be similar to the method for forming the insulating layer 6. Through the above series of steps, another wiring layer having a wiring and an insulating layer is formed. That is, the wiring structure 1A including a plurality of wiring layers can be obtained. A series of steps for forming the wiring layer described above may be performed not only once but also a plurality of times. According to the method for producing the wiring structure 1A according to the modified example, the wiring structure 1A including the multilayered wiring layers can be produced.

### REFERENCE SIGNS LIST

1, 1A wiring structure
2 support substrate
2a main surface
3,7 conductor layer
4 resist
5,8 wiring
6,9 insulating layer
21 modification region
41 opening pattern.

1. A method for producing a wiring structure comprising:
forming, in a support substrate, a modification region lying along a main surface of the support substrate and exposed on the main surface;
forming a conductor layer on the main surface so as to adhere with the modification region;
forming a wiring on the conductor layer;
forming an insulating layer on the conductor layer to cover the wiring;
separating the support substrate from the conductor layer; and
removing the conductor layer.

2. The method for producing a wiring structure according to claim 1, wherein the modification region includes a hole communicating from the main surface.

3. The method for producing a wiring structure according to claim 1, wherein the forming the modification region includes forming the modification region by performing plasma treatment on the support substrate.

4. The method for producing a wiring structure according to claim 1, wherein an adhesion strength between the conductor layer and the modification region is 0.1 to 1.0 N/mm.

5. The method for producing a wiring structure according to claim 1, wherein a thickness of the modification region is 50 nm to 500 nm.

6. The method for producing a wiring structure according to claim 1, wherein a thickness of the conductor layer is 50 nm to 1 μm.

7. The method for producing a wiring structure according to claim 1, wherein the forming the wiring includes:
forming a resist on the conductor layer;
forming an opening pattern in which the conductor layer is exposed in the resist;
filling the opening pattern with a conductive material by electroplating to form the wiring; and
removing the resist.

8. The method for producing a wiring structure according to claim 7, wherein the resist is formed of a photosensitive material.

9. The method for producing a wiring structure according to claim 1, wherein the insulating layer is formed of a thermosetting resin.

10. The method for producing a wiring structure according to claim 1, further comprising forming a plurality of multilayered wiring layers by performing a series of steps including, after forming the insulating layer, forming another conductor layer on the insulating layer, forming another wiring on the another conductor layer, and forming another insulating layer to cover the another wiring one or more times.
